(19) United States
(12) Patent Application Publication
(10) Pub. No.: US 2025/0309207 A1
(43) Pub. Date: Oct. 2, 2025

(54) DISPLAY PANEL AND DISPLAY DEVICE

(71) Applicant: Tianma Advanced Display Technology Institute (Xiamen) Co., Ltd., Xiamen (CN)

(72) Inventors: Xiaoyun CHEN, Xiamen (CN); Yongfeng LIU, Xiamen (CN); Rong HU, Xiamen (CN); Liang XING, Xiamen (CN)

(73) Assignee: Tianma Advanced Display Technology Institute (Xiamen) Co., Ltd., Xiamen (CN)

(21) Appl. No.: 18/733,883

(22) Filed: Jun. 5, 2024

(30) Foreign Application Priority Data
Mar. 29, 2024 (CN) 202410381309.3

(51) Int. Cl. H01L 25/16; H01L 27/12

(52) U.S. Cl. CPC H01L 25/167; H10D 86/441; H10D 86/60

(57) ABSTRACT

Embodiments of the application provide a display panel and a display device. The display panel includes: a display area including a pixel area, the pixel area including light emitting elements; and a first light transmitting area and a second light transmitting area, the first light transmitting area having an area of S1 and the second light transmitting area having an area of S2; wherein |S1−S2|>0. The display panel includes at least two light transmitting areas with different light transmitting areas, and by reasonably setting the positions of the light transmitting areas with different areas, the transparent display panel can be further designed depending on different application scenarios or different needs, and thus satisfy different usage needs of users.

### CROSS-REFERENCE TO RELATED APPLICATIONS

This application claims priority to Chinese Patent Application No. 202410381309.3, titled “DISPLAY PANEL AND DISPLAY DEVICE” and filed on Mar. 29, 2024, which is hereby incorporated by reference in its entirety.

### TECHNICAL FIELD

The present application relates to the technical field of display devices, and particularly to a display panel and a display device.

### BACKGROUND

With rapid development of electronic devices, users' requirements for display panels are becoming higher and more diverse. For example, in order to improve a screen-to-body ratio of the display panel, a light-sensitive element can be integrated under the screen of the display panel, which requires the display panel to have certain light transmitting properties; or a light transmitting display device can be provided directly to meet different needs of the users. However, current display panels cannot well meet different needs of the users.

### SUMMARY

Embodiments according to a first aspect of the application provide a display panel. The display panel includes: a display area including a pixel area, the pixel area including light emitting elements; and a first light transmitting area and a second light transmitting area, the first light transmitting area having an area of S1 and the second light transmitting area having an area of S2; wherein |S1−S2|>0.

Embodiments according to a second aspect of the application provide a display device including a display panel, wherein the display panel includes: a display area including a pixel area, the pixel area including light emitting elements; and a first light transmitting area and a second light transmitting area, the first light transmitting area having an area of S1 and the second light transmitting area having an area of S2; wherein |S1−S2|>0.

### BRIEF DESCRIPTION OF THE DRAWINGS

Other features, purposes and advantages of the present application will be more apparent by reading the following detailed description of the non-restrictive embodiments with reference to the drawings. Here, the same or similar reference numbers indicate the same or similar features, and the drawings are not drawn to actual scale.

FIG. 1 is a schematic structural diagram of a display panel provided by the present application;

FIG. 2 is a schematic diagram of a locally enlarged structure at P in FIG. 1;

FIG. 3 is a cross-sectional view at A-A in FIG. 2 in an embodiment;

FIG. 4 is a cross-sectional view at A-A in FIG. 2 in another embodiment;

FIG. 5 is a schematic structural diagram of a first pixel driving circuit of a display panel provided by the present application;

FIG. 6 is a layout diagram of a first pixel driving circuit of a display panel provided by the present application;

FIG. 7 is a schematic diagram of a locally enlarged structure at M in FIG. 1 in an example;

FIG. 8 is a layout diagram of a first pixel driving circuit of another display panel provided by the present application;

FIG. 9 is a layout diagram of a partial film layer structure of a display panel in an example;

FIG. 10 is a layout diagram of another partial film layer structure of a display panel in an example;

FIG. 11 is a schematic diagram of a locally enlarged structure at M in FIG. 1 in another example;

FIG. 12 is a schematic diagram of a locally enlarged structure at Q in FIG. 1 in an example;

FIG. 13 is a schematic diagram of a locally enlarged structure at Q in FIG. 1 in another example;

FIG. 14 is a schematic structural diagram of a display panel provided by another embodiment of the present application;

FIG. 15 is a schematic diagram of a locally enlarged structure at Q in FIG. 1 in another example;

FIG. 16 is a schematic diagram of a locally enlarged structure at Q in FIG. 1 in yet another example;

FIG. 17 is a schematic diagram of a locally enlarged structure at Q in FIG. 1 in yet another example;

FIG. 18 is a cross-sectional view at B-B in FIG. 17;

FIG. 19 is a schematic diagram of a locally enlarged structure at Q in FIG. 1 in yet another example;

FIG. 20 is a schematic diagram of a locally enlarged structure at F in FIG. 1;

FIG. 21 is a cross-sectional view at C-C in FIG. 20;

FIG. 22 is a schematic structural diagram of a display device provided by the present application.

### DETAILED DESCRIPTION

Features and exemplary embodiments of various aspects of the present application are described in detail below. In the following detailed description, a number of specific details are presented in order to provide a full understanding of the present application. However, it will be apparent to those skilled in the art that the present application can be implemented without some of these specific details. The following description of embodiments is provided solely for the purpose of providing a better understanding of the present application by illustrating examples of the application. In the accompanying drawings and the following description, at least some of the well-known structures and techniques are not illustrated in order to avoid unnecessary ambiguity to the present application; and the dimensions of some of the structures may be exaggerated for clarity. Furthermore, the features, structures, or characteristics described below may be combined in one or more embodiments in any suitable manner.

In the description of the application, it is noted that, unless otherwise indicated, the term “plurality” means more than two; the terms “top,” “bottom,” “left,” “right,” “inside,” “outside,” and the like indicate orientation or positional relationships only for the purpose of facilitating the description of the present application and simplifying the description, but not intended to indicate or imply that the device or element referred to must have a particular orientation, be constructed and operated in a particular orientation, and therefore are not to be construed as a limitation of the present application. Furthermore, the terms “first”, “second”, and the like are used for descriptive purposes only, but not to be construed as indicating or implying relative importance.

Orientation terms appearing in the following description are orientations shown in the drawings, but not intended to limit specific structures of embodiments of the present application. In the description of the present application, it should also be noted that, unless otherwise expressly specified and limited, the terms “mounted” and “connected” are to be understood broadly, e.g., they may be fixedly connected, removably connected, or integrally connected; they may be directly connected, or indirectly connected. For a person of ordinary skill in the art, specific meanings of the above terms in the present application may be understood in the context of specific situations.

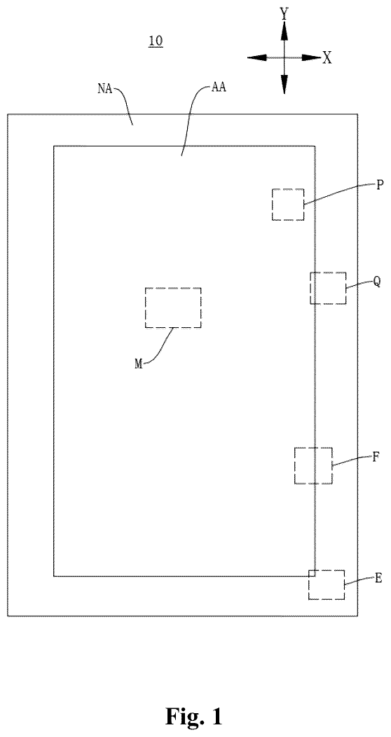

For better understanding of the present application, the display panel and display device of embodiments of the present application will be described in detail below in conjunction with FIGS. 1 to 21.

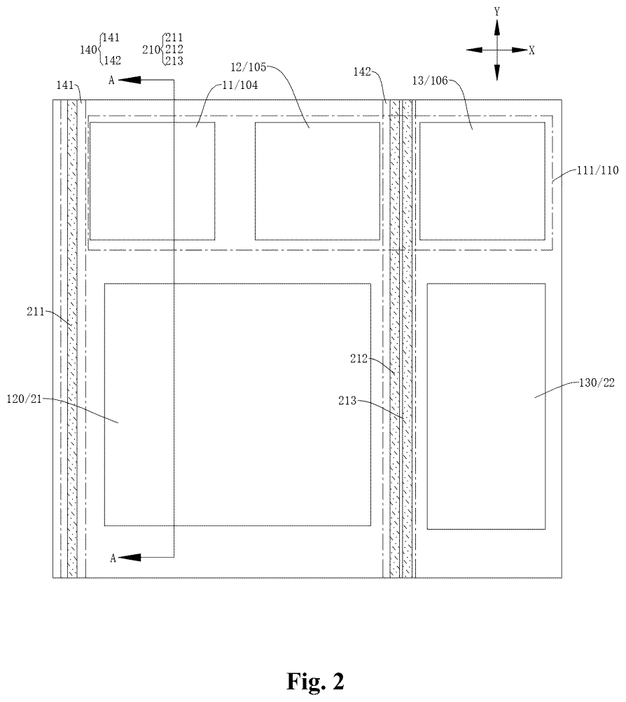

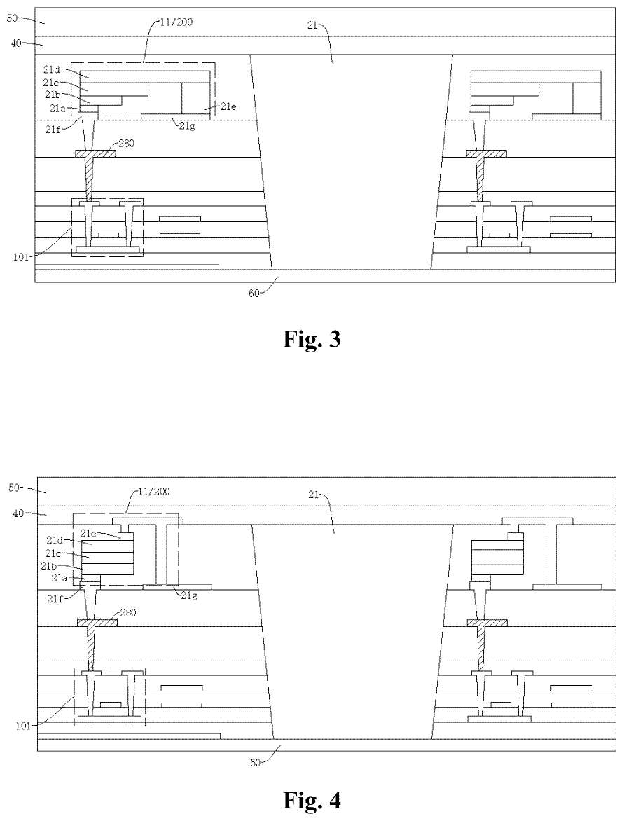

FIG. 1 is a schematic structural diagram of a display panel 10 provided by the present application, FIG. 2 is a schematic diagram of a locally enlarged structure at P in FIG. 1, and FIG. 3 is a sectional view at A-A of FIG. 2 in an embodiment.

As shown in FIGS. 1 to 3, an embodiment of the present application provides a display panel 10 including a display area AA, a first light transmitting area 120 and a second light transmitting area 130; the display area AA includes a pixel area 110, and the pixel area 110 includes light emitting elements 200; the first light transmitting area 120 has an area of S1 and the second light transmitting area 130 has an area of S2, where |S1-S2|>0.

In the display panel 10 provided by embodiments of the application, the pixel area 110 is disposed in the display area AA of the display panel 10 and the light emitting elements 220 in the pixel area 110 are used to realize the light emitting display of the display panel 10. The display panel 10 also includes the first light transmitting area 120 and the second light transmitting area 130, and the light transmitting area S1 of the first light transmitting area 120 is different from the light transmitting area S2 of the second light transmitting area 130. That is, the display panel 10 includes at least two light transmitting areas with different light transmitting areas, and by reasonably setting the positions of the light transmitting areas with different areas, the transparent display panel 10 can be further designed depending on different application scenarios or different needs, and thus satisfy different usage needs of users.

Optionally, the light emitting element 200 of the pixel area 110 may be selected from at least one of an organic light emitting diode, a micro light emitting diode, and a liquid crystal light emitting unit.

As shown in FIGS. 3 and 4, in the embodiments of the present application, the micro light emitting diode is taken as an example of the light emitting element 200 for illustration. Optionally, the light emitting element 200 includes at least a first electrode 21a, a first semiconductor 21b, a light emitting portion 21c, a second semiconductor portion 21d, and a second electrode 21e.

Optionally, as shown in FIG. 3, the light emitting element 200 is an inverted micro light emitting diode. The light emitting portion 21c is located between the first semiconductor 21b and the second semiconductor portion 21d, and the first electrode 21a and the second electrode 21e are located on the same side of the light emitting portion 21c.

Or optionally, as shown in FIG. 4, the light emitting element 200 is a vertical micro light emitting diode. The light emitting portion 21c is located between the first semiconductor 21b and the second semiconductor portion 21d, and the first electrode 21a and the second electrode 21e are located on different sides of the light emitting portion 21c, the first electrode 21a is located on the side of the first semiconductor 21b away from the light emitting portion 21c, and the second electrode 21e is located on the side of the second semiconductor portion 21d away from the light emitting portion 21c.

In other embodiments, the light emitting element 200 may also be a horizontal micro light emitting diode, i.e., the first electrode 21a, the first semiconductor 21b, the light emitting portion 21c, the second semiconductor portion 21d, and the second electrode 21e of the light emitting element 200 are provided in a stack in a direction parallel to a light-out surface of the display panel.

Optionally, the material of the first semiconductor 21b may be a P-type semiconductor material, such as P-type gallium nitride, and then the material of the second semiconductor section 21d is an N-type semiconductor material, such as N-type gallium nitride. Since the P-type semiconductor material relies on hole conductivity, a positive voltage is needed, that is, in this case, the first electrode 21a located on the side of the first semiconductor 21b away from the light emitting portion 21c the can be a positive electrode; and since the N-type semiconductor material relies on electron conductivity, a negative voltage is needed, that is, in this case, the second electrode 21e located on the side of the second semiconductor portion 21d away from the light emitting portion 21c can be a negative electrode; the light emitting portion 21c can be a multi-quantum well layer, and holes and electrons combine at the light emitting portion 21c, causing the micro light emitting diode to emit light. It is to be understood that the present embodiment only exemplifies the electrode types and semiconductor materials of the first electrode 21a, the first semiconductor 21b, the second semiconductor portion 21d, and the second electrode 21e, and in specific implementations, when the material of the first semiconductor 21b may be an N-type semiconductor material, the type of the rest of the structure may be selectively changed.

Optionally, the display panel 10 may also include a thin film transistor disposed in the pixel area 110 to cause the thin film transistor T to drive the light emitting element 200 to emit light. The first light transmitting area 120 and the second light transmitting area 130 have large light transmittance, so as to allow a light-sensitive element to be disposed in these areas or enable the display panel to realize a transparent display function. The shape of the first light transmitting area 120 and the second light transmitting area 130 may be a rectangle as shown in FIG. 2, or may be a circle, an oval, or other regular or irregular shape.

Optionally, in FIG. 2, the first light transmitting area 120 and the second light transmitting area 130 located in the display area AA are taken as an example for illustration. In other optional embodiments, the display panel 10 further includes a non-display area NA provided surrounding the display area AA, and the first light transmitting area 120 and the second light transmitting area 130 may also both be located in the non-display area NA, or alternatively, one of the first light transmitting area 120 and the second light transmitting area 130 is located in the display area AA, and the other is located in the non-display area NA.

Optionally, the display panel 10 also includes a non-display area NA, and the non-display area NA may be provided surrounding the display area AA, i.e., the non-display area NA may be a border area of the display panel 10; alternatively, the display area AA may be provided surrounding the non-display area NA, e.g., the non-display area NA may be a light transmitting aperture area of the display panel 10, so that the light-sensitive element acquires ambient light information through the light transmitting aperture area. In the embodiments of the present application, the non-display area NA being a border area of the display panel 10 is taken as an example for illustration.

In yet other embodiments, the display panel 10 may be a full-screen display panel 10, and the display panel 10 may not include the non-display area NA, and in this case, the first light transmitting area 120 and the second light transmitting area 130 are located in the display area AA. In the embodiments, the display panel 10 including the display area AA and the non-display area NA is taken as an example for illustration.

Optionally, the light emitting element 200 is not provided within the first light transmitting area 120 and the second light transmitting area 130, i.e., the first light transmitting area 120 and the second light transmitting area 130 are light transmitting and non-displayable, so as to ensure that the first light transmitting area 120 and the second light transmitting area 130 have better light transmittance. Optionally, signal lines and devices such as thin film transistors T are not provided in the first light transmitting area 120 and the second light transmitting area 130, so as to improve the light transmittance of the first light transmitting area 120 and the second light transmitting area 130.

In some optional embodiments, the transmittance of the first light transmitting area 120 and/or the second light transmitting area 130 is greater than the transmittance of the pixel area 110, so that the overall transmittance of the display panel 10 can be increased by providing the first light transmitting area 120 and/or the second light transmitting area 130. Also, the pixel area 110 has a lower transmittance, which can address the influence of ambient light on the display effect when the ambient light transmits through the display panel 10, and improve the display effect of the display panel 10. The transmittance herein refers to the transmittance of light.

In some optional embodiments, please continue to refer to FIGS. 1 and 2, the first light transmitting area 120 and the second light transmitting area 130 are located in the display area AA; the display area AA also includes a wiring area 140; and the first light transmitting area 120 and the second light transmitting area 130 are located on two sides of the pixel area 110 or the wiring area 140, respectively.

In these optional embodiments, the first light transmitting area 120 and the second light transmitting area 130 are located in the display area AA to improve the light transmittance and light transmitting uniformity of the display area AA, and the first light transmitting area 120 and the second light transmitting area 130 are located on two sides of the pixel area 110 or the wiring area 140, respectively, to address the influence of the first light transmitting area 120 and the second light transmitting area 130 on the wiring in the wiring area 140 or the light emitting elements 200 in the pixel area 110.

Optionally, the wiring area 140 may be used for disposing signal wirings such as data signal lines 210, scanning signal lines, and the like. Optionally, the transmittance of the wiring area 140 is less than the transmittances of the first light transmitting area 120 and the second light transmitting area 130.

Optionally, the first light transmitting area 120 and the second light transmitting area 130 may be located on two sides of the wiring area 140, and/or, the first light transmitting area 120 and the second light transmitting area 130 may be located on two sides of the pixel area 110.

In some optional embodiments, the pixel area 110 includes a first pixel area 111, the first pixel area 111 including a first sub-pixel 11, a second sub-pixel 12, and a third sub-pixel 13; the first sub-pixel 11 and the second sub-pixel 12 correspond to the first light transmitting area 120, and the third sub-pixel 13 corresponds to the second light transmitting area 130; where S1>S2.

In these optional embodiments, the first pixel area 111 includes a first sub-pixel 11, a second sub-pixel 12, and a third sub-pixel 13, and the first sub-pixel 11, the second sub-pixel 12, and the third sub-pixel 13 may be used to emit light of different colors to realize the light emitting display of the display panel 10. The first sub-pixel 11 and the second sub-pixel 12 correspond to the first light transmitting area 120, for example, the first sub-pixel 11 and the second sub-pixel 12 are provided side-by-side with the first light transmitting area 120, and the third sub-pixel 13 is provided side-by-side with the second light transmitting area 130. That is, the first light transmitting area 120 and two sub-pixels are provided side-by-side, and the second light transmitting area 130 and one sub-pixel are provided side-by-side, so that the setting area S1 of the first light transmitting area 120 may be larger than the setting area S2 of the second light transmitting area 130. The first sub-pixel 11 and the second sub-pixel 12 are not provided with a wiring area 140 between them, the wiring area 140 is located on a side of the first sub-pixel 11 away from the second sub-pixel 12 or the wiring area 140 is located on a side of the second sub-pixel 12 away from the first sub-pixel 11, and the first sub-pixel 11 and the second sub-pixel 12 correspondingly form a larger first light transmitting area 120. Furthermore, by providing the first light transmitting area 120 and the second light transmitting area 130 as corresponding to different sub-pixels, a segmentation design is applied for the first pixel area 111, which facilitates the wiring in the first pixel area 111, reduces the distances between the wiring and different sub-pixels in the first pixel area 111, and also makes the first light transmitting area 120 and the second light transmitting area 130 flexible in terms of the location where they are disposed, so that the first light transmitting area 120 and the second light transmitting area 130 may have different areas, and thus the transparent display panel 10 may be further designed depending on different application scenarios or different needs.

Optionally, the first sub-pixel 11, the second sub-pixel 12 and the third sub-pixel 13 are used to emit light of different colors, and the first sub-pixel 11, the second sub-pixel 12 and the third sub-pixel 13 may be used to form a pixel unit for emitting white light. For example, the first sub-pixel 11 is a red sub-pixel, the second sub-pixel 12 is a blue sub-pixel, and the third sub-pixel 13 is a green sub-pixel. Optionally, the first sub-pixel 11, the second sub-pixel 12 and the third sub-pixel 13 form a pixel repeating unit, a plurality of pixel repeating units are distributed in rows and columns to form a pixel arrangement structure of the display panel 10, and the first pixel area 111 includes a plurality of sub-pixels in a pixel repeating unit.

Optionally, the first sub-pixel 11, the second sub-pixel 12 and the third sub-pixel 13 may be arranged in rows and columns along the first direction X and the second direction Y. For example, the first sub-pixel 11, the second sub-pixel 12 and the third sub-pixel 13 are sequentially arranged along the first direction X and located in the same row, and a plurality of first pixel areas 111 are arranged along the first direction X to form a pixel row.

The first sub-pixel 11 and the second sub-pixel 12 corresponding to the first light transmitting area 120 may be: the first sub-pixel 11 and the second sub-pixel 12 are disposed side by side with the first light transmitting area 120 along the second direction Y. Optionally, an extension length of the first light transmitting area 120 in the first direction X may be less than or equal to an extension length of the first sub-pixel 11 and the second sub-pixel 12 in the first direction X, so that the first light transmitting area 120 does not interfere with the signal wiring step for connecting the first sub-pixel 11 and the second sub-pixel 12.

Similarly, the third sub-pixel 13 corresponding to the second light transmitting area 130 may be: the third sub-pixel 13 and the second light transmitting area 130 are disposed side by side along the second direction Y. Optionally, an extension length of the second light transmitting area 130 in the first direction X may be less than or equal to an extension length of the third sub-pixel 13 in the first direction X.

In some optional embodiments, the wiring area 140 includes a first wiring area 141 and a second wiring area 142; the first light transmitting area 120 and the second light transmitting area 130 are located on two sides of the second wiring area 142, respectively; the wiring area 140 includes data signal lines 210, and the number of data signal lines 210 in the first wiring area 141 is less than the number of data signal lines 210 in the second wiring area 142.

In these optional embodiments, the wiring area 140 is divided into the first wiring area 141 and the second wiring area 142, and the data signal lines 210 for connecting the first sub-pixel 11, the second sub-pixel 12, and the third sub-pixel 13 may be located in the first wiring area 141 and the second wiring area 142. The first light transmitting area 120 and the second light transmitting area 130 are located on two sides of the second wiring area 142, and the second wiring area includes a large number of data signal lines 210, so that the data signal lines 210 within the second wiring area 142 can connect the sub-pixels located on two sides of the second wiring area 142.

Optionally, the first sub-pixel 11, the second sub-pixel 12, and the third sub-pixel 13 are arranged in a sequential order, the second wiring area 142 is accordingly located between the second sub-pixel 12 and the third sub-pixel 13, and the data signal lines 210 within the second wiring area 142 can be used to connect the second sub-pixel 12 and the third sub-pixel 13. The data signal lines 210 within the first wiring area 141 can be used to connect the first sub-pixel 11. On the basis of dividing the wiring area 140 into the first wiring area 141 and the second wiring area 142, by reasonably setting the number of data signal lines in different wiring areas 140 and the positional relationship between the data signal lines 210 and different sub-pixels within the wiring area 140, the distance between the data signal line 210 and the sub-pixel connected thereto can be reduced. Optionally, the first wiring area 141 and the second wiring area 142 may be provided extending along the second direction Y. The first wiring area 141 is located on the side of the first sub-pixel 11 facing away from the second sub-pixel 12, and the second wiring area 142 is located between the second sub-pixel 12 and the third sub-pixel 13, so as to facilitate interconnection between the data signal lines 210 within the first wiring area 141 and the first sub-pixel 11, and connection between the data signal lines 210 within the second wiring area 142 and the second sub-pixel 12 and the third sub-pixel 13, reduce the distance between the data signal line 210 and the sub-pixel adjacent thereto, reduce the extension length of the data signal line 210, reduce the distribution area of the data signal line 210, and thus further improve the light transmittance of the display panel 10.

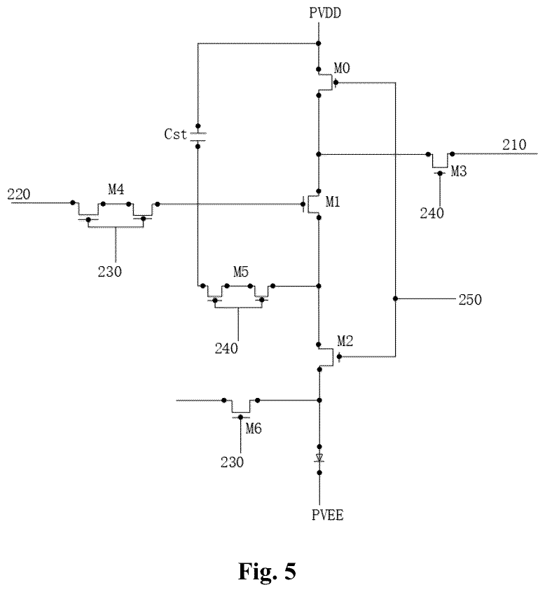

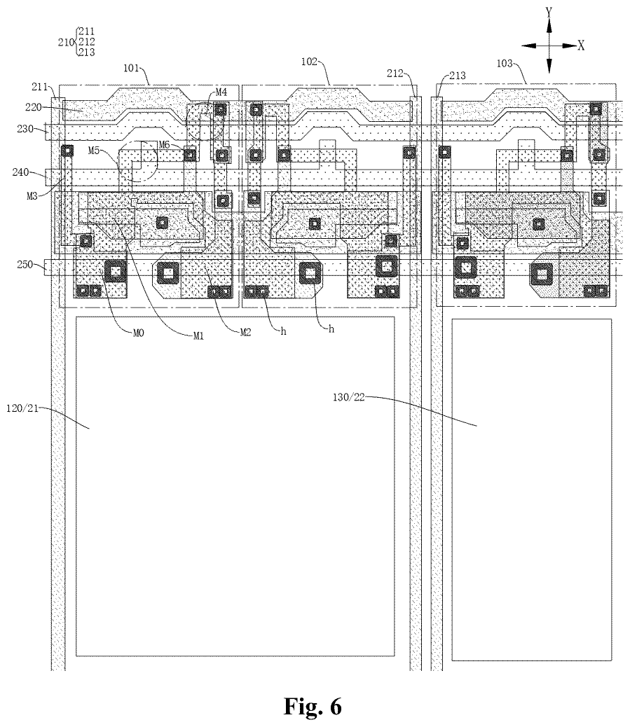

Referring to FIGS. 1 to 6 together, FIG. 5 is a diagram of a pixel driving circuit of a display panel 10 provided by an embodiment of the present application, and FIG. 6 is a layout diagram of a first pixel driving circuit of a display panel 10 provided by an embodiment of the present application.

In some optional embodiments, as shown in FIGS. 1 to 6, the first sub-pixel 11 includes a first pixel driving circuit 101, the second sub-pixel 12 includes a second pixel driving circuit 102, and the third sub-pixel 13 includes a third pixel driving circuit 103; the first pixel driving circuit 101 and the second pixel driving circuit 102 are in mirror symmetry, and the second pixel driving circuit 102 and the third pixel driving circuit 103 are in mirror symmetry.

Optionally, the circuit structure of the first pixel driving circuit 101 is shown in FIG. 5, and the layout of the first pixel driving circuit 101 is shown in FIG. 6. Optionally, FIG. 6 may be considered to be a layout diagram of the pixel driving circuit structure corresponding to the schematic diagram of the structure shown in FIG. 2. That is, FIG. 2 illustrates the relative positions of the first pixel area 111, the first light transmitting area 120, the second light transmitting area 130, and the wiring area 140, and FIG. 6 illustrates, in the first pixel area 111, the structures of the first pixel driving circuit 101, the second pixel driving circuit 102, and the third pixel driving circuit 103, and the signal wiring provided in the wiring area 140. In order to more clearly show the via connection relationship between the film layers, FIG. 6 schematically illustrates the locations of the connection vias h for connecting the film layers. FIG. 6 illustrates two different sizes of the vias h. The embodiments of the present application do not limit the sizes of the vias h, as long as they can realize the via connection between the different film layers.

As shown in FIGS. 2 and 6, the data signal lines 210 include a first data signal line 211, a second data signal line 212, and a third data signal line 213. The first data signal line 211 is located in the first wiring area 141, and the second data signal line 212 and the third data signal line 213 are located in the second wiring area 142. The first light transmitting area 120, the first pixel driving circuit 101, the second pixel driving circuit 102 are located between the first wiring area 141 and the second wiring area 142, and the second light transmitting area 130 and the third pixel driving circuit 103 are located on the side of the second wiring area 142 facing away from the first light transmitting area 120. The first pixel driving circuit 101 and the first data signal line 211 within the first wiring are 141 are electrically connected to each other, the second pixel driving circuit 102 and the second data signal line 212 within the second wiring area 142 are electrically connected to each other, and the third pixel driving circuit 103 and the third data signal line 213 within the second wiring area 142 are electrically connected to each other. Since the first pixel driving circuit 101 and the second pixel driving circuit 102 are in mirror symmetry, the first pixel driving circuit 101 and the second pixel driving circuit 102 are respectively connected with the first data signal line 211 and the second data signal line 212 disposed on both sides thereof.

In the embodiments of the present application, the first pixel driving circuit 101 and the second pixel driving circuit 102 are in mirror symmetry, and the second pixel driving circuit 102 and the third pixel driving circuit 103 are in mirror symmetry. The second pixel driving circuit 102 does not need to be electrically connected to the signal lines within the first wiring area 141 across the first pixel driving circuit 101, so that the distance between the second pixel driving circuit 102 and the second data signal line 212 connected thereto can be reduced; similarly, the first pixel driving circuit 101 does not need to be electrically connected to the signal lines within the second wiring area 142 across the second pixel driving circuit 102, so that the distance between the first pixel driving circuit 101 and the first data signal line 211 connected thereto can be reduced, and the third pixel driving circuit 103 does not need to straddle the other pixel driving circuits, so that the distance between the third pixel driving circuit 103 and the third data signal line 213 can be reduced. Therefore, the wiring distribution area can be reduced, and the light transmittance of the display panel can be improved. In addition, the present application is also capable of simplifying the distribution pattern of the pixel driving circuit.

Optionally, as shown in FIGS. 3 to 6, the display panel further includes a first pad 21f and a second pad 21g, the first pad 21f is connected to the first electrode 21a, the second pad 21g is connected to the second electrode 21e, and one of the first pad 21f and the second pad 21g is connected to the pixel driving circuit. For example, the first electrode 21a of the light emitting element 200 of the first sub-pixel 11 is connected to the first pixel driving circuit 101 through the first pad 21f, the first electrode 21a of the light emitting element 200 of the second sub-pixel 12 is connected to the second pixel driving circuit 102 through the first pad 21f, the first electrode 21a of the light emitting element 200 of the third sub-pixel 13 is connected to the third pixel driving circuit 103 through the first pad 21f. Optionally, the first pad 21f and the pixel driving circuit may be connected directly through a via, or a conductive layer is provided between the first pad 21f and the pixel driving circuit, a connection portion 280 is provided within the conductive layer, and the first pad 21f and the pixel driving circuit are connected to each other through the connection portion 280.

Optionally, the first sub-pixel 11 further includes a first light emitting unit 104, the second sub-pixel 12 further includes a second light emitting unit 105, and the third sub-pixel 13 further includes a third light emitting unit 106. The first electrode 21a of the first light emitting unit 104 is electrically connected to the first pixel driving circuit 101, the first electrode 21a of the second light emitting unit 105 is electrically connected to the second pixel driving circuit 102, and the first electrode 21a of the third light emitting unit 106 is electrically connected to the third pixel driving circuit 103.

In some optional embodiments, as shown in FIGS. 5 and 6, the first pixel driving circuit 101 includes a first data writing transistor M3 and a first driving transistor M1, the data signal lines 210 include the first data signal line 211, the first data signal line 211 is electrically connected to the first data writing transistor M3, and the first data writing transistor M3 is located on a side of the first driving transistor M1 close to the first data signal line 211. It is possible to reduce the distance between the first data writing transistor M3 and the first data signal line 211, reduce the wiring distribution area, and further improve the light transmittance of the display panel 10.

In some optional embodiments, the second pixel driving circuit 102 includes a second data writing transistor and a second driving transistor, the data signal lines 210 include the second data signal line 212, the second data signal line 212 is electrically connected to the second data writing transistor, and the second data writing transistor is located on a side of the second driving transistor close to the second data signal line 212. It is possible to reduce the distance between the second data writing transistor and the second data signal line 212, reduce the wiring distribution area, and further improve the light transmittance of the display panel 10.

In some optional embodiments, the third pixel driving circuit 103 includes a third data writing transistor and a third driving transistor, the data signal lines 210 include the third data signal line 213, the third data signal line 213 is electrically connected to the third data writing transistor, and the third data writing transistor is located on a side of the third driving transistor close to the third data signal line 213. It is possible to reduce the distance between the third data writing transistor and the third data signal line 213, reduce the wiring distribution area, and further improve the light transmittance of the display panel 10.

Optionally, the first data signal line 211 is located in the first wiring area 141, the second data signal line 212 and the third data signal line 213 are located in the second wiring area 142, and the second data signal line 212 is located on a side of the third data signal line 213 close to the second data writing transistor, so as to further reduce the distance between the data writing transistor and the data line connected thereto, reduce the wiring distribution area, and further improve the light transmittance of the display panel 10.

Optionally, the first pixel driving circuit 101, the second pixel driving circuit 102, and the third pixel driving circuit 103 have the same circuit structure. The data signal lines 210 include the first data signal line 211, the second data signal line 212, and the third data signal line 213. The first data signal line 211 is connected to the first pixel driving circuit 101, the second data signal line 212 is connected to the second pixel driving circuit 102, and the third data signal line 213 is connected to the third pixel driving circuit 103.

Optionally, as shown in FIGS. 5 and 6, the structure of the pixel driving circuit according to the embodiments of the present application is illustrated by taking the first pixel driving circuit 101 as an example. The first pixel driving circuit 101 may further include a first power writing transistor M0, a first light emitting control transistor M2, a first pixel electrode reset transistor M6, a first threshold compensation transistor M5, a first gate reset transistor M4, and a storage capacitor Cst. The display panel 10 may further include a first scanning signal line 230, a second scanning signal line 240, a light emitting control signal line 250, a reference voltage signal line 220, a drive power voltage signal line PVDD, and a negative power voltage signal line PVEE.

Optionally, the first power writing transistor M0 and the first light emitting control transistor M2 are connected to the light emitting control signal line 250, and the data writing transistor M3 is connected to the data signal line 210 and the second scanning signal line 240, for example, the data writing transistor M3 of the first pixel driving circuit 101 is connected to the first data signal line 211. The first gate reset transistor M4 is connected to the first scanning signal line 230 and the reference voltage signal line 220, the first threshold compensation transistor M5 is a dual gate transistor and connected to the second scanning signal line 240, and the third reset transistor M6 is connected to the first scanning signal line 230. The first power writing transistor M0 is connected to the drive power voltage signal line PVDD. The pixel driving circuit is also connected to the negative power voltage signal line PVEE.

Optionally, the first power writing transistor M0 and the first light emitting control transistor M2 are disposed on a side of the first driving transistor M1 facing the first light transmitting area 120, and the first power writing transistor M0 and the first light emitting control transistor M2 are spaced apart along the first direction X and both connected to the light emitting control signal line 250. The first threshold compensation transistor M5 and the first pixel electrode reset transistor M6, the first data writing transistor M3 and the first gate reset transistor M4 are located on a side of the first driving transistor M1 facing away from the first light transmitting area 120.

Optionally, the first wiring area 141, the second wiring area 142, the first sub-pixel 11, the second sub-pixel 12, the third sub-pixel 13, the first light transmitting area 120, and the second light transmitting area 130 form a repeating unit, and a plurality of repeating units are arranged side-by-side along the first direction X. The third sub-pixels 13 and the first sub-pixels 11 of adjacent repeating units are adjacent to each other, and the first wiring area 141 is located between two adjacent repeating units.

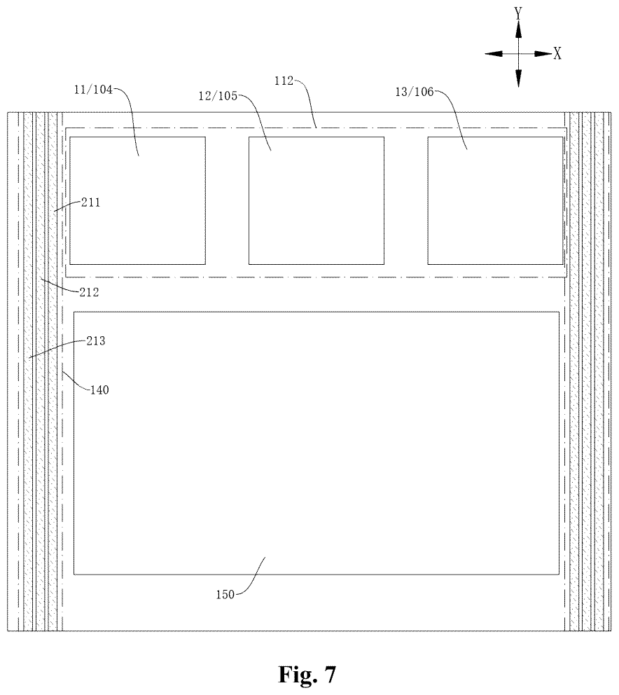

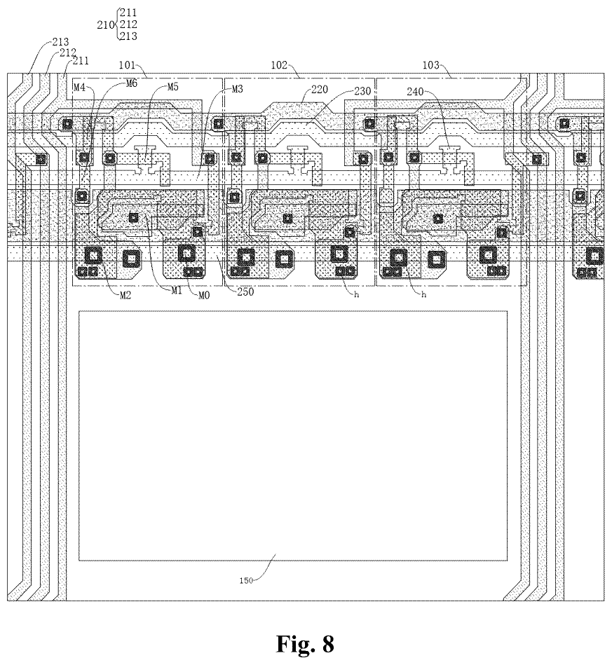

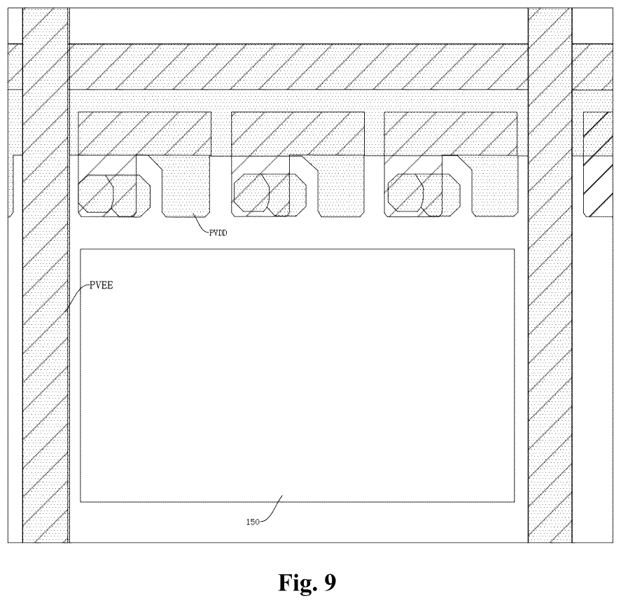

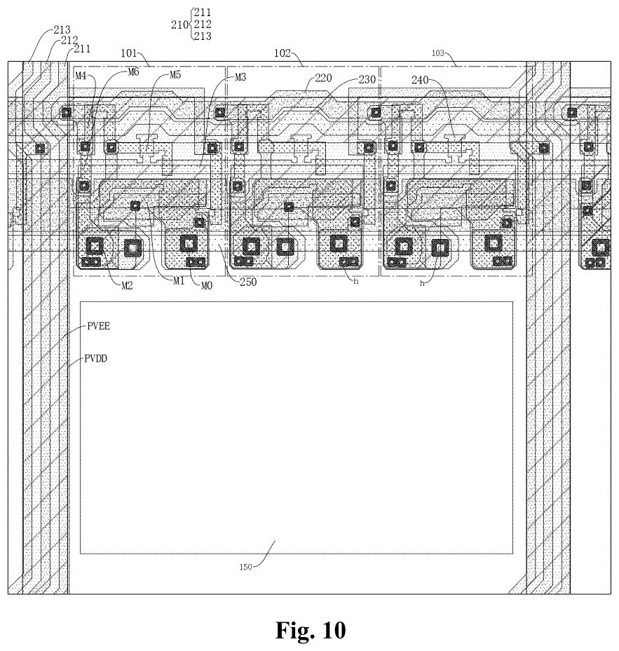

Referring to FIGS. 1 to 10 together, FIG. 7 is a schematic diagram of a locally enlarged structure at M in FIG. 1 in another example, FIG. 8 is a layout diagram of a pixel driving circuit of a display panel in an example; FIG. 9 is a layout diagram of a partial film layer of a display panel in an example, and FIG. 10 is a layout diagram of another partial film layer of a display panel in an example.

In some optional embodiments, as shown in FIGS. 1 to 10, the pixel area 110 includes a second pixel area 112, and the second pixel area 112 includes a first sub-pixel 11, a second sub-pixel 12, and a third sub-pixel 13; the display panel 10 further includes a third light transmitting area 150, the second pixel area 112 corresponds to the third light transmitting area 150, and the third light transmitting area 150 has an area of S3; where S3>S1.

In these optional embodiments, the pixel area 110 further includes the second pixel area 112, the second pixel area 112 includes three sub-pixels, and the third light transmitting area 150 is provided as corresponding to the three sub-pixels of the second pixel area 112. In the embodiments of the present application, the third light transmitting area 150 corresponding to three sub-pixels is provided in addition to the first light transmitting area 120 corresponding to two sub-pixels and the second light transmitting area 130 corresponding to one sub-pixel as described above, which can enrich the setting methods of the light transmitting area. In addition, the third light transmitting area 150 is arranged as corresponding to three sub-pixels, which can increase the arrangement area of the third light transmitting area 150 and thereby improve the light transmittance of the display panel 10.

Optionally, FIG. 8 may be considered to be a layout diagram of the structure of the pixel driving circuit corresponding to the schematic diagram of the structure shown in FIG. 7. That is, FIG. 7 illustrates the relative positions of the second pixel area 112 and the third light transmitting area 150. FIG. 8 illustrates, in the second pixel area 112, the structures of the first pixel driving circuit 101, the second pixel driving circuit 102, and the third pixel driving circuit 103, and the signal wiring provided in the wiring area 140. FIG. 8 also illustrates connection vias h between the film layers, and the vias h are provided in the manner described above and not repeated here. In order to show the structures of the first pixel driving circuit 101, the second pixel driving circuit 102, and the third pixel driving circuit 103 more clearly, the drive power voltage signal line PVDD and the negative power voltage signal line PVEE shown in FIG. 9 are omitted from FIG. 8. FIG. 10 contains the structure of each of the film layers shown in FIG. 8 and the structure of each of the film layers shown in FIG. 9, and FIG. 10 schematically illustrates the position relationship between the structure of the film layers shown in FIG. 8 and the structure of the film layers shown in FIG. 9. As described above, the pixel area 110 includes the first pixel area 111 and the second pixel area 112, and the first pixel area 111 and the second pixel area 112 both include the first sub-pixel 11, the second sub-pixel 12, and the third sub-pixel 13. Optionally, the first sub-pixel 11, the second sub-pixel 12, and the third sub-pixel 13 included within the first pixel area 111 may be arranged in the same way as the first sub-pixel 11, the second sub-pixel 12, and the third sub-pixel 13 included within the second pixel area 112, and the first pixel area 111 and the second pixel area 112 differ in their different positions and the different light transmitting areas corresponding to the first sub-pixel 11, the second sub-pixel 12 and the third sub-pixel 13 within them.

As shown in FIGS. 7 and 8, the second pixel area 112 is provided with the first sub-pixel 11, the second sub-pixel 12 and the third sub-pixel 13, and the first sub-pixel 11, the second sub-pixel 12 and the third sub-pixel 13 are provided corresponding to the third light transmitting area 150. The first data signal line 211, the second data signal line 212, and the third data signal line 213 are provided on two sides of the second pixel area 112, i.e., the first data signal line 211, the second data signal line 212, and the third data signal line 213 are located in the same wiring area 140 which is located on two sides of the second pixel area 112 and the third light transmitting area 150 disposed corresponding to the wiring area 140.

Optionally, taking the view direction of FIGS. 7 and 8 as an example, the first pixel driving circuit 101 may be connected to the first data signal line 211 located on the left side of the third light transmitting area 150, the second pixel driving circuit 102 may be connected to the second data signal line 212 located on the right side of the third light transmitting area 150, and the third pixel driving circuit 103 may be connected to the third data signal line 213 located on the right side of the third light transmitting area 150. That is, the second pixel driving circuit 102 and the third pixel driving circuit 103 are connect to the data signal lines 210 located on the same side of the third light transmitting area 150 to reduce the distances between the pixel driving circuits and the corresponding data signal lines 210. In other embodiments, the second pixel driving circuit 102 may also be connected to the second data signal line 212 located on the left side of the third light transmitting area 150, i.e., the second pixel driving circuit 102 and the first pixel driving circuit 101 are connected to the data signal lines 210 located on the same side of the third light transmitting area 150.

Optionally, FIGS. 7, 8, and 6 differ in that the wiring area 140, the third light transmitting area 150, and the second pixel area 112 are provided at different locations, the transistors within the second pixel driving circuit 102 and the third pixel driving circuit 103 are provided at different locations in FIGS. 7 and 8, and the electrical connection relationship between the transistors in the pixel driving circuits of FIGS. 7 and 8 can be seen from FIG. 5.

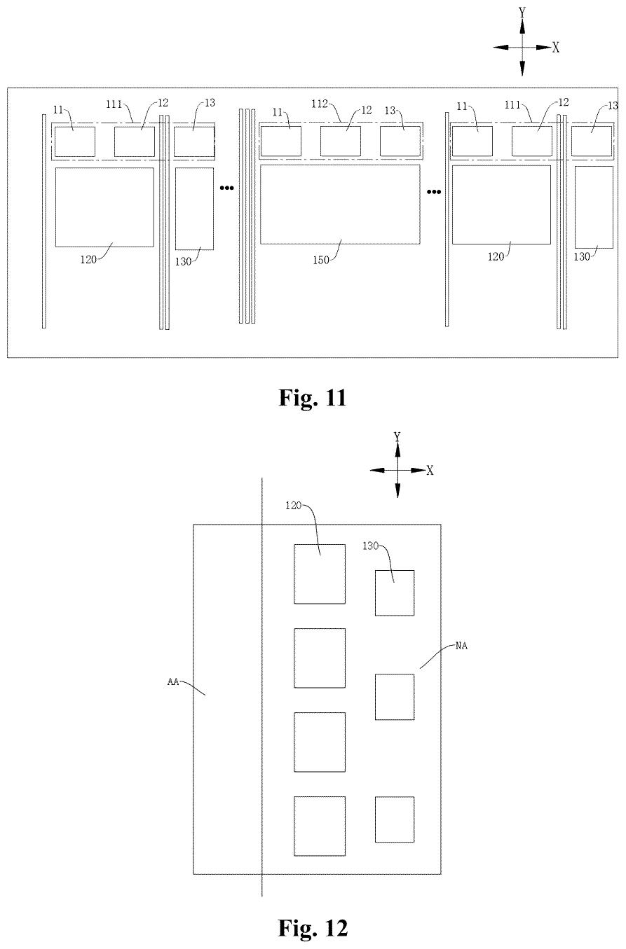

Optionally, as shown in FIG. 11, the second pixel area 112 is located on the side of the first pixel area 111 away from the non-display area NA, i.e., the second pixel area 112 is disposed closer to the center of the display area AA than the first pixel area 111.

Optionally, as described above, when the first sub-pixel 11, the second sub-pixel 12 and the third sub-pixel 13 are arranged side-by-side along the first direction X and the second direction Y, a plurality of second pixel areas 112 may be arranged in a row along the first direction X to form a pixel row, and the third light transmitting area 150 and the second pixel area 112 may be arranged side-by-side along the second direction Y. Optionally, an extension length of the third light transmitting area 150 in the first direction X may be less than or equal to an extension length of the second pixel area 112 in the first direction X. Optionally, as described above, the display panel 10 may also include the non-display area NA provided surrounding the display area AA. The non-display area NA is usually provided with light-shielding components such as wirings, which causes the light transmittance of the non-display area NA to be significantly smaller than the transmittance of the display area AA.

In some optional embodiments, the second light transmitting area 130 is located on a side of the first light transmitting area 120 facing the non-display area NA, and/or, the first light transmitting area 120 is located on a side of the third light transmitting area 150 facing the non-display area NA. That is, along the direction towards the non-display area NA, the area of the light transmitting area within the display area AA gradually decreases, which better addresses the problem of uneven light transmittance between the display area AA and the non-display area NA.

As shown in FIG. 11, the display panel may include the first light transmitting area 120, the second light transmitting area 130, and the third light transmitting area 150 Optionally, as shown in FIG. 11, within the display area AA, the first light transmitting area 120 is located on the side of the second light transmitting area 130 facing the non-display area NA, and the third light transmitting area 150 is located on the side of the second light transmitting area 130 facing away from the non-displayed area NA. That is, along the direction towards the non-display area NA, the area of the light transmitting area within the display area AA gradually decreases, which better addresses the problem of uneven light transmittance between the display area AA and the non-display area NA.

FIG. 11 only illustrates the relative positions of the first light transmitting area 120, the second light transmitting area 130, the third light transmitting area 150, the first pixel area 111 and the second pixel area 112. The pixel circuit layout in the second pixel area 112 can be seen from FIGS. 8 and 10, and the pixel circuit layout in the first pixel area 111 can be seen from FIG. 6.

The light transmitting area may be provided in various ways, for example, the light transmitting area may be provided with vias. In some other optional embodiments, referring to FIGS. 1 to 4 together, the display panel 10 includes a first film layer 20, and the first film layer 20 includes a first opening 21 located in the first light transmitting area 120 and a second opening 22 located in the second light transmitting area 130. By providing the first opening 21 and the second opening 22, the transmittance of the first light transmitting area 120 and the second light transmitting area 130 can be increased.

Optionally, the first opening 21 and/or the second opening 22 may be filled with a transparent filling portion, and the transmittance of the transparent filling portion is greater than the transmittance of the first film layer 20. By adding the transparent filling portion, the overall flatness of the first film layer 20 can be improved while ensuring that the first light transmitting area 120 and the second light transmitting area 130 have relatively high transmittance.

The first film layer 20 may be a single-layer structural layer, or the first film layer 20 may include a plurality of sub-layers provided in a stack. The embodiments of the present application are illustrated by taking the first film layer 20 including a plurality of film layers as an example. The first opening 21 may be provided penetrating the first film layer 20, or the first opening 21 may be formed by a surface depression of the first film layer 20. That is, the first film layer 20 may be perforated to increase the transmittance, or the transmittance may be increased by reducing a partial thickness of the first film layer 20. Similarly, the second opening 22 may be provided penetrating the first film layer 20, or the second opening 22 may be formed by a surface depression of the first film layer 20. That is, the first film layer 20 may be perforated to increase the transmittance, or the transmittance may be increased by reducing a partial thickness of the first film layer 20.

The first film layer 20 may include an organic film layer and/or an inorganic film layer. When the first film layer 20 includes an organic film layer, the first film layer 20 may include a photoresist or the like. In this case, the first film layer 20 may be prepared by a process such as coating or printing. When the first film layer 20 includes an inorganic film layer, the first film layer 20 may include silicon oxide and/or silicon nitride, etc. In this case, the first film layer 20 may be prepared by a process such as deposition.

As described in FIGS. 3 and 4, the display panel 10 may further include a substrate 60, the first pixel driving circuit 101 may be provided on the substrate 60, and the first light emitting unit 104 is provided on a side of the first pixel driving circuit 101 facing away from the substrate 60. Optionally, the display panel 10 may further include a cover plate 50 located on a side of the first light emitting unit 104 facing away from the substrate 60. Optionally, an adhesive layer 40 may also be provided between the cover plate 50 and the first light emitting unit 104.

Referring to FIGS. 1 and 12 together, FIG. 12 is a schematic diagram of a locally enlarged structure at Q in FIG. 1 in an example.

In some optional embodiments, as shown in FIGS. 1 and 12, the first light transmitting area 120 and the second light transmitting area 130 are both located in the non-display area NA to increase the transmittance of the non-display area NA and thereby increase the overall transmittance of the display panel 10. In addition, by adding the first light transmitting area 120 and the second light transmitting area 130 in the non-display area, the transmittance of the non-display area will increase as the area ratio of the first light transmitting area 120 and the second light transmitting area 130 increases. The transmittance of the non-display area can be increased by reasonably setting the distribution area of the first light transmitting area 120 and the second light transmitting area 130, so as to reduce the presence of the border and improve the display effect of the transparent screen.

There are various ways of arranging the first light transmitting area 120 and the second light transmitting area 130 in the non-display area NA. For example, the first light transmitting area 120 and the second light transmitting area 130 may be distributed on a side of the display area AA along an extension direction of the non-display area NA.

In some other embodiments, please continue to refer to FIG. 12, the second light transmitting area 130 is located on a side of the first light transmitting area 120 facing away from the display area AA; where S1>S2. The non-display area NA is usually used for setting light-shielding components such as wiring, resulting in a low transmittance of the non-display area NA. In the embodiments of the present application, by arranging the first light transmitting area 120 having a larger distribution area in the non-display area NA to be close to the display area AA, the light transmittance in the non-display area NA gradually increases along the direction toward the display area AA, which addresses the display difference between the display area AA and the non-display area NA and improves the overall light transmitting effect of the display panel 10. By adopting gradually distributed light transmitting areas, an effect of gradually changing transmittance can be achieved. That is, the light transmitting area located close to the display area AA has a relatively large area, and the light transmitting area located away from the display area AA has a relatively small area. In this way, it is possible to further alleviate the problem of the obviousness of the boundary between the display area AA and the non-display area NA.

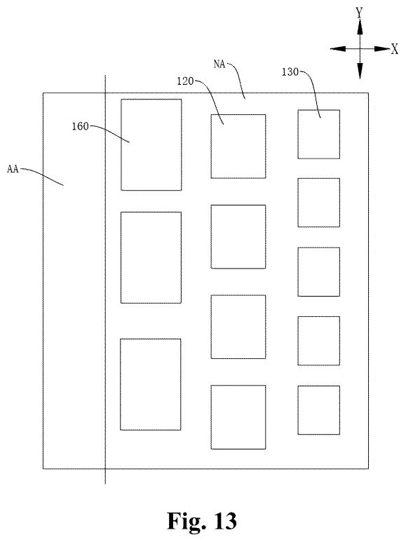

Referring to FIGS. 1 and 13 together, FIG. 13 is a schematic diagram of a locally enlarged structure at Q in FIG. 1 in another example.

In some optional embodiments, the display panel 10 further includes a fourth light transmitting area 160 located in the non-display area NA, the fourth light transmitting area 160 has an area of S4, and the fourth light transmitting area 160 is located on the side of the first light transmitting area 120 facing the display area AA; where S4>S1>S2.

In these optional embodiments, by adding the fourth light transmitting area 160, the shapes and setting methods of the light transmitting areas can be enriched, and by arranging the fourth light transmitting area 160 with a larger area on a side close to the display area AA, the problem of a large transmittance difference between the display area AA and the non-display area NA can be better addressed.

In some optional embodiments, S4−S1=S1−S2, or S4/S1=S1/S2. That is, the distribution areas of the fourth light transmitting area 160, the first light transmitting area 120, and the second light transmitting area 130 vary with an equal difference or an equal ratio, so that the transition of the transmittance of the display panel 10 in the direction from the display area AA to the non-display area NA can be more uniform.

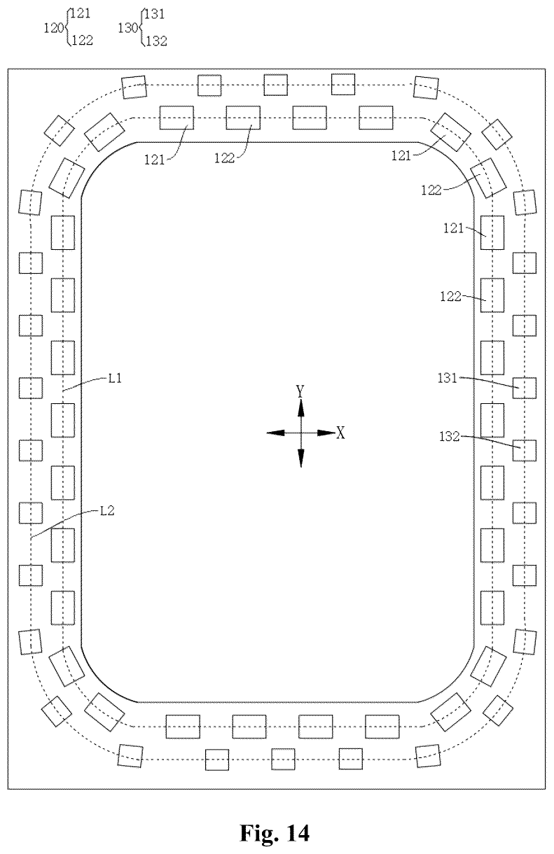

In some optional embodiments, as shown in FIG. 14, the first light transmitting area 120 includes a first sub-area 121 and a second sub-area 122 spaced apart along a first predetermined direction, and a distance from the first sub-area 121 to the display area AA is equal to a distance from the second sub-area 122 to the display area AA.

In these optional embodiments, the distances from the first sub-area 121 and the second sub-area 122 of the first light transmitting area 120 to the display area AA are equal, so that the transmittance of the non-display area NA at different positions in the first direction X can be more uniform, the transmittance of the non-display area NA arranged surrounding the display area AA can be more uniform at different positions, and the light transmitting effect of the display panel 10 can be further improved.

Optionally, as shown in FIG. 14, the non-display area NA may include two first non-display areas relatively arranged along the first direction X and two second non-display areas relatively arranged along the second direction Y. The two first non-display areas and the two second non-display areas are alternately connected head-to-tail to surround the display area AA.

When the first sub-area 121 and the second sub-area 122 are located within the first non-display area, the first predetermined direction may be the second direction Y, the first sub-area 121 and the second sub-area 122 are spaced apart along the second direction Y, and along the first direction X, a distance between the first sub-area 121 and the display area AA is equal to a distance from the second sub-area 122 to the display area AA, so that the transmittance within the first non-display area at different locations along the second direction Y can be more uniform.

When the first sub-area 121 and the second sub-area 122 are located within the second non-display area, the first predetermined direction may be the first direction X, the first sub-area 121 and the second sub-area 122 are spaced apart along the first direction X, and along the second direction Y, a distance between the first sub-area 121 and the display area AA is equal to a distance from the second sub-area 122 to the display area AA, so that the transmittance within the second non-display area at different locations along the first direction X can be more uniform.

Optionally, please continue to refer to FIG. 14, the second light transmitting area 130 includes a third sub-area 131 and a fourth sub-area 132 spaced apart along the first predetermined direction, and a distance from the third sub-area 131 to the display area AA is equal to a distance from the fourth sub-area 132 to the display area AA, so that the transmittance of the non-display area NA at different positions in the first direction X can be more uniform, the transmittance of the non-display area NA arranged surrounding the display area AA can be more uniform at different positions, and the light transmitting effect of the display panel 10 can be further improved.

As described above, when the non-display area NA includes the first non-display area and the second non-display area, the third sub-area 131 and the fourth sub-area 132 may be located in the first non-display area and/or the second non-display area. When the third sub-area 131 and the fourth sub-area 132 are located within the first non-display area, the first predetermined direction may be the second direction Y, the third sub-area 131 and the fourth sub-area 132 are spaced apart along the second direction Y, and along the first direction X, a distance between the third sub-area 131 and the display area AA is equal to a distance from the fourth sub-area 132 to the display area AA, so that the transmittance within the first non-display area at different locations along the second direction Y can be more uniform.

When the third sub-area 131 and the fourth sub-area 132 are located within the second non-display area, the first predetermined direction may be the first direction X, the third sub-area 131 and the fourth sub-area 132 are spaced apart along the first direction X, and along the second direction Y, a distance between the third sub-area 131 and the display area AA is equal to a distance from the fourth sub-area 132 to the display area AA, so that the transmittance within the second non-display area at different locations along the first direction X can be more uniform.

Optionally, as shown in FIG. 14, the first sub-area 121 and/or the second sub-area 122 and the second light transmitting area 130 may be arranged side-by-side. For example, when the first sub-area 121, the second sub-area 122, the third sub-area 131 and the fourth sub-area 132 are located in the same first non-display area, the first sub-area 121 and the third sub-area 131 may be arranged side-by-side along the first direction X, and the second sub-area 122 and the fourth sub-area 132 may be arranged side-by-side along the first direction X.

Optionally, as shown in FIG. 14, a plurality of first light transmitting areas 120 are arranged at intervals along the first trajectory L1 surrounding the display area AA, and the first trajectory L1 is arranged at an equal spacing from the boundary of the display area AA, i.e., different parts of the first trajectory L1 are at equal minimum distances from the boundary of the display area AA. In these embodiments, by arranging the plurality of first light transmitting areas 120 at intervals along the first trajectory L1 surrounding the display area AA, the transmittance change of the display panel is more uniform at different positions of the boundary between the display area AA and the non-display area NA.

Optionally, the plurality of first light transmitting areas 120 arranged at intervals along the first trajectory L1 surrounding the display area AA may be provided in such a way that the geometric centers of the plurality of first light transmitting areas 120 projected along the thickness direction of the display panel are arranged at intervals along the first trajectory L1.

Optionally, as shown in FIG. 14, a plurality of second light transmitting areas 130 are arranged at intervals along the second trajectory L2 surrounding the display area AA, and the second trajectory L2 is arranged at an equal spacing from the boundary of the display area AA, i.e., different parts of the second trajectory L2 are at equal minimum distances from the boundary of the display area AA. In these embodiments, by arranging the plurality of second light transmitting areas 130 at intervals along the second trajectory L2 surrounding the display area AA, the transmittance change of the display panel is more uniform at different positions of the boundary between the display area AA and the non-display area NA.

Optionally, the first trajectory L1 and the second trajectory L2 are provided at equal spacing from each other, so that the transmittance change of the display panel is more uniform along the direction from the display area AA to the non-display area NA.

In some embodiments, as shown in FIG. 14, a boundary exists between the display area AA and the non-display area NA, and when the boundary extends along the second direction Y, the first sub-area 121 and the second sub-area 122 may be spaced apart along the second direction Y, and the first predetermined direction is the second direction Y. Please continue to refer to FIG. 14, when a corner exists in the display area AA and the boundary of the display area AA and the non-display area NA extends along a direction intersecting the first direction X, the first sub-area 121 and the second sub-area 122 may extend along an extension direction of the boundary adjacent thereto, i.e., the first sub-area 121 and the second sub-area 122 also extend along the direction intersecting the first direction X. Similarly, the third sub-area 131 and the fourth sub-area 132 may also extend along the direction intersecting the first direction X.

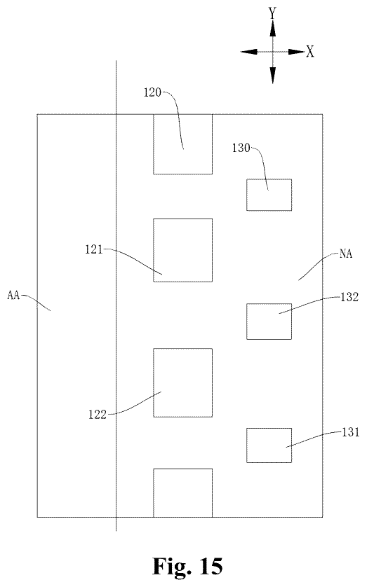

In some other optional embodiments, as shown in FIGS. 14 and 15, the first sub-area 121 and/or the second sub-area 122 and the second light transmitting area 130 are at least partially non-overlapping along a second predetermined direction, the second predetermined direction intersecting the first predetermined direction. That is, at least parts of the first light transmitting area 120 and the second light transmitting area 130 are misaligned, and at least part of the second light transmitting area 130 corresponds to an area between the first sub-area 121 and the second sub-area 122 adjacent thereto, so that the light transmitting areas are more uniformly distributed to improve the uniformity of light transmitting of the non-display area NA.

For example, as shown in FIG. 14, when the first sub-area 121, the second sub-area 122, the third sub-area 131 and the fourth sub-area 132 are located in the same first non-display area, the first sub-area 121 and the third sub-area 131 may be provided at least partially non-overlapping along the first direction X, and the second sub-area 122 and the fourth sub-area 132 may be provided at least partially non-overlapping along the first direction X. For example, the first sub-area 121 and the second sub-area 122 are arranged in a first light transmitting column along the second direction Y, the third sub-area 131 and the fourth sub-area 132 are arranged in a second light transmitting column along the second direction Y. The first light transmitting column and the second light transmitting column are misaligned, at least part of the third sub-area 131 corresponds to an area between the first sub-area 121 and the second sub-area 122 adjacent thereto, and at least part of the fourth sub-area 132 corresponds to an area between the first sub-area 121 and the second sub-area 122 adjacent thereto, so that the light transmitting areas are more uniformly distributed to improve the uniformity of light transmitting of the non-display area NA.

For example, as shown in FIG. 15, the first sub-area 121 and/or the second sub-area 122 do not overlap at all with the second light transmitting area 130 along the second predetermined direction. For example, the first sub-area 121 does not overlap at all with the third sub-area 131 and the fourth sub-area 132, and the second sub-area 122 does not overlap at all with the third sub-area 131 and the fourth sub-area 132, so that the light transmitting areas are more uniformly distributed to improve the uniformity of light transmitting of the non-display area NA.

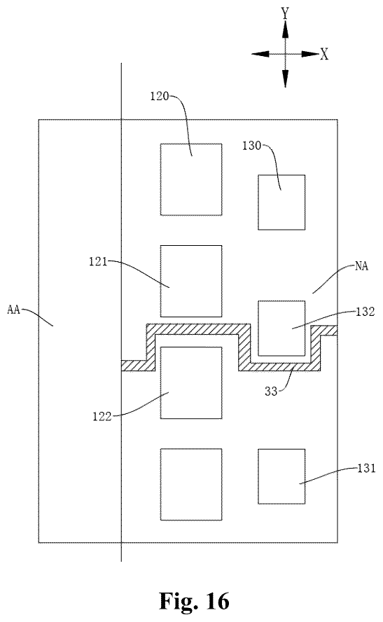

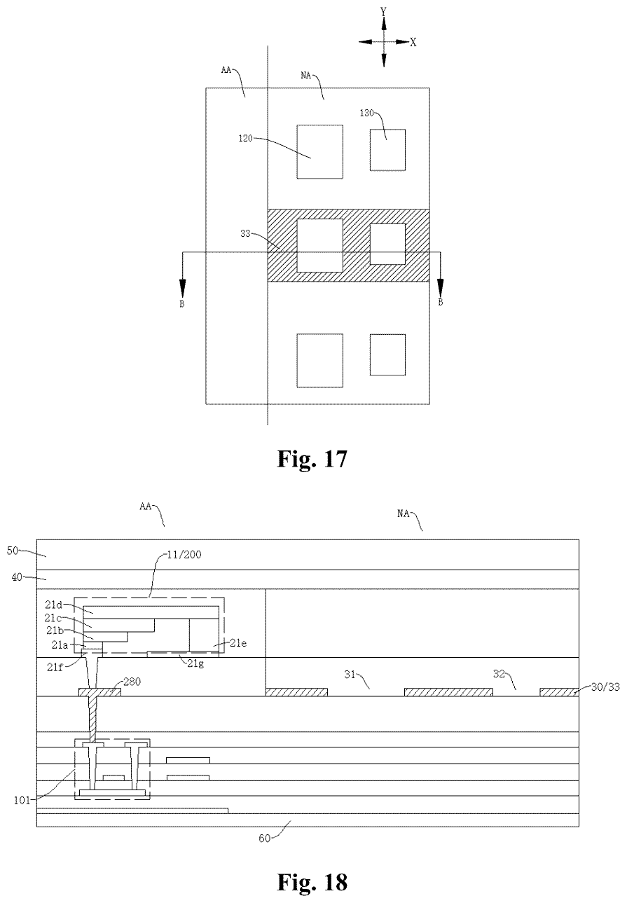

Optionally, as shown in FIGS. 16 and 17, the display panel 10 further includes a first signal line 33 located in the non-display area NA. The first signal line 33 may be arranged surrounding the first light transmitting area 120 and the second light transmitting area 130, and an extension path of the first signal line 33 may be folded.

Optionally, as shown in FIG. 16, when the first light transmitting area 120 includes the first sub-area 121 and the second sub-area 122, the first signal line 33 may be arranged surrounding the first sub-area 121 or the second sub-area 122. When the second light transmitting area 130 includes the third sub-area 131 and the fourth sub-area 132, the first signal line 33 may be arranged surrounding the third sub-area 131 or the fourth sub-area 132.

In some other optional embodiments, referring to FIGS. 17 and 18 together, the display panel 10 includes a second film layer 30, and the second film layer 30 includes a third opening 31 located in the first light transmitting area 120 and a fourth opening 32 located in the second light transmitting area 130. By providing the third opening 31 and the fourth opening 32, the transmittance of the first light transmitting area 120 and the second light transmitting area 130 can be increased.

Optionally, the third opening 31 and/or the fourth opening 32 may be filled with a transparent filling portion, and the transmittance of the transparent filling portion is greater than the transmittance of the second film layer 30. By adding the transparent filling portion, the overall flatness of the second film layer 30 can be improved while ensuring that the first light transmitting area 120 and the second light transmitting area 130 have relatively high transmittance.

The second film layer 30 may include an organic film layer and/or an inorganic film layer. When the second film layer 30 includes an organic film layer, the second film layer 30 may include a photoresist or the like. In this case, the second film layer 30 may be prepared by a process such as coating or printing. When the second film layer 30 includes an inorganic film layer, the second film layer 30 may include silicon oxide and/or silicon nitride, etc. In this case, the second film layer 30 may be prepared by a process such as deposition.

The second film layer 30 may be an insulating film layer. For example, the display panel 10 further includes a cover 50 and an adhesive layer 40 provided on an inner side of the cover 50, and the adhesive layer 40 may be reused as the second film layer 30.

Alternatively, the second film layer 30 is a metal film layer, and the second film layer 30 includes the first signal line 33 described above, and the first signal line 33 includes the third opening 31 and the fourth opening 32. The third opening 31 and the fourth opening 32 may be formed by punching holes in the first signal line 33 with a low light transmittance, which can increase the transmittance of the first light transmitting area 120 and the second light transmitting area 130.

Optionally, as an example, FIG. 18 illustrates the second film layer 30 includes the first signal line 33 described above, and the first signal line 33 may be in the same layer as the connection portion 280. In other embodiments, the first signal line 33 may also be provided in the same layer as one of the capacitor plates of the storage capacitor Cst.

Optionally, referring to FIG. 13, FIG. 17, and FIG. 18 together, when the display panel 10 includes the fourth light transmitting area 160, the second film layer 30 may also include a fifth opening located in the fourth light transmitting area 160, and the first signal line 33 may include the fifth opening described above so as to further increase the transmittance.

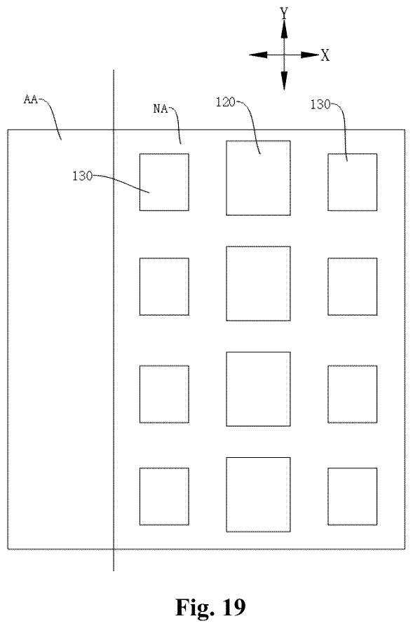

In some other embodiments, as shown in FIG. 19, the number of second light transmitting areas 130 is more than two, and at least two second light transmitting areas 130 are respectively disposed on two sides of the first light transmitting area 120 to increase the arrangement diversity of the light transmitting areas in the non-display area NA.

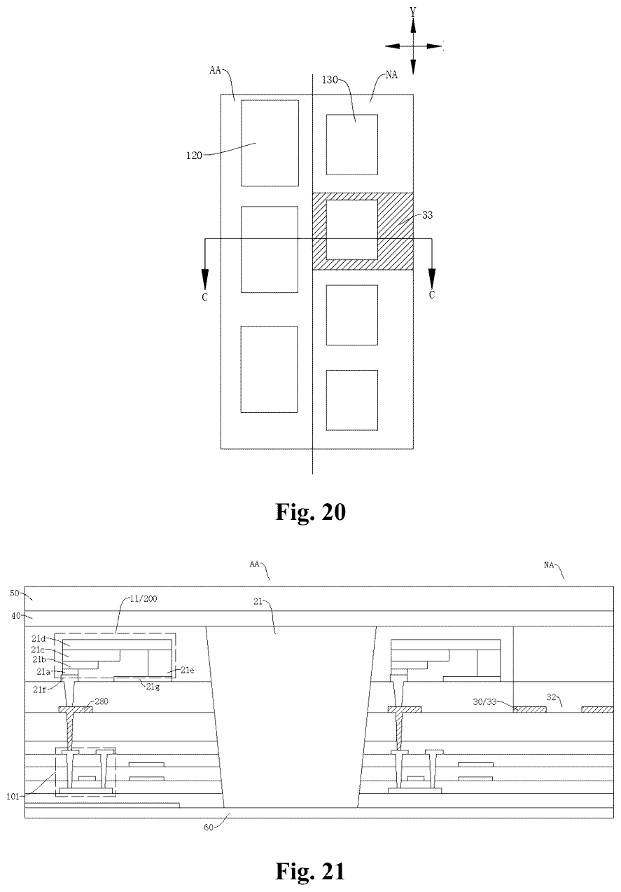

In yet other embodiments, as shown in FIGS. 20 and 21, one of the first light transmitting area 120 and the second light transmitting area 130 may be located in the display area AA, and the other may be located in the non-display area NA. For example, the first light transmitting area 120 is located in the display area AA, and the second light transmitting area 130 is located in the non-display area NA; where S1>S2. By arranging the first light transmitting area 120 having a larger distribution area in the display area AA, the light transmittance of the display area AA of the display panel 10 can be increased.

As shown in FIGS. 20 and 21, the non-display area NA is provided with the first signal line 33, the first signal line 33 is reused as the second film layer 30, and the first signal line 33 includes the fourth opening 32 located in the second light transmitting area 130, so as to increase the light transmittance of the non-display area NA. The display area AA includes the first opening 21 located in the second light transmitting area 120 to increase the light transmittance of the display area AA.

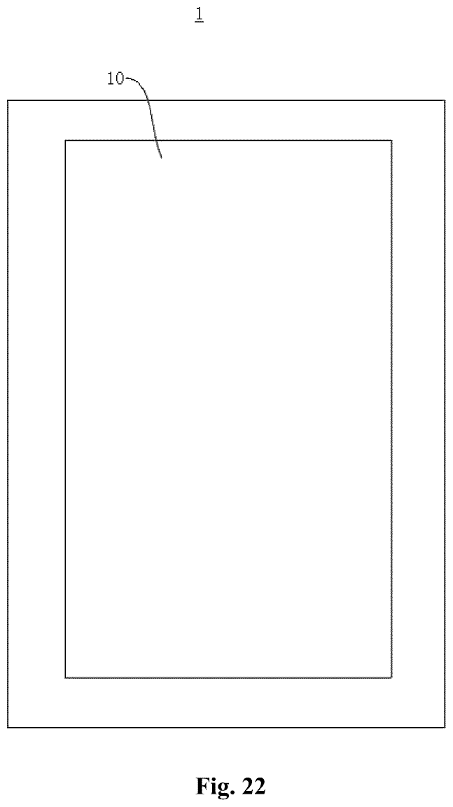

As shown in FIG. 22, the embodiments of the second aspect of the present application further provide a display device 1 including the display panel 10 according to any of the above-described embodiments of the first aspect. Since the display device 1 provided by the embodiments of the second aspect of the present application includes the display panel 10 according to any of the above-described embodiments of the first aspect, the display device 1 provided by the embodiments of the second aspect of the present application has the same beneficial effect as the display panel 10 according to any of the above-described embodiments of the first aspect, which will not be repeated here.

In any of the above embodiments, a color changing layer may also be provided within the non-display area NA, and the color changing layer includes a color changing material. By controlling the color changing range and transparency of the color changing material, the transparency of a non-transparent area can be further controlled. For example, the transparency of an area close to the display area AA can be made higher to achieve the effect of extending the wiring of the transparent area and thus changing the shape of the transparent area. The color changing layer may be provided in the first light transmitting area 120 and/or the second light transmitting area 130, and the shape of the color changing layer may be set to be the same as that of the first light transmitting area 120 and/or the second light transmitting area 130. That is, the first light transmitting area 120 and/or the second light transmitting area 130 may be provided with a color changing material, and by controlling the color changing range and the transparency of the color changing material, it is possible to further control the transparency of the non-display area NA. Alternatively, the first light transmitting area 120 and/or the second light transmitting area 130 may be provided within an opening of the color changing layer, and by adjusting the transparency of the color changing layer, the light transmittance of the non-display area NA can be adjusted.

The display device 1 in the embodiments of the present application includes, but is not limited to, a cell phone, a Personal Digital Assistant (PDA), a tablet computer, an e-book, a television set, a doorstop, a smart landline phone, a console, and other devices with display functions.

Although the present application has been described with reference to the preferred embodiments, various improvements can be made and parts thereof can be replaced with equivalents without departing from the scope of the present application. In particular, as long as there is no structural conflict, each of the technical features mentioned in various embodiments can be combined in any manner. The present application is not limited to the particular embodiments disclosed herein, but includes all technical solutions falling within the scope of the claims.

What is claimed is:

1. A display panel, comprising:
a display area including a pixel area, the pixel area including light emitting elements; and
a first light transmitting area and a second light transmitting area, the first light transmitting area having an area of S1 and the second light transmitting area having an area of S2; wherein
$$\vert S 1 - S 2 \vert > 0.$$

2. The display panel according to claim 1, wherein
transmittance of the first light transmitting area and/or the second light transmitting area is greater than transmittance of the pixel area.

3. The display panel according to claim 1, wherein
the first light transmitting area and the second light transmitting area are located in the display area;
the display area further includes a wiring area; the first light transmitting area and the second light transmitting area are located on two sides of the pixel area or the wiring area respectively.

4. The display panel according to claim 3, wherein
the pixel area includes a first pixel area, the first pixel area including a first sub-pixel, a second sub-pixel and a third sub-pixel;
the first sub-pixel and the second sub-pixel correspond to the first light transmitting area, and the third sub-pixel corresponds to the second light transmitting area; wherein
S1>S2.

5. The display panel according to claim 4, wherein
the wiring area includes a first wiring area and a second wiring area; the first light transmitting area and the second light transmitting area are located on two sides of the second wiring area respectively;
the wiring area includes data signal lines, and the number of data signal lines in the first wiring area is smaller than the number of data signal lines in the second wiring area.

6. The display panel according to claim 5, wherein
the first sub-pixel includes a first pixel driving circuit, the second sub-pixel includes a second pixel driving circuit, and the third sub-pixel includes a third pixel driving circuit;
the first pixel driving circuit and the second pixel driving circuit are in mirror symmetry, and the second pixel driving circuit and the third pixel driving circuit are in mirror symmetry.

7. The display panel according to claim 6, wherein
the first pixel driving circuit includes a first data writing transistor and a first driving transistor, the data signal line includes a first data line, the first data line is electrically connected to the first data writing transistor, and the first data writing transistor is located on a side of the first driving transistor close to the first data line.

8. The display panel according to claim 4, wherein
the pixel area includes a second pixel area, the second pixel area including a first sub-pixel, a second sub-pixel and a third sub-pixel;
the display panel further includes a third light transmitting area, the second pixel area corresponds to the third light transmitting area, and the third light transmitting area has an area of S3; wherein
S3>S1.

9. The display panel according to claim 8, wherein
the display panel further includes a non-display area at least partially surrounding the display area; the second light transmitting area is located on a side of the first light transmitting area facing the non-display area, and/or, the first light transmitting area is located on a side of the third light transmitting area facing the non-display area.

10. The display panel according to claim 1, wherein
the display panel includes a first film layer, the first film layer including a first opening located in the first light transmitting area and a second opening located in the second light transmitting area.

11. The display panel according to claim 1, wherein
the display panel further includes a non-display area at least partially surrounding the display area; the first light transmitting area and the second light transmitting area are both located in the non-display area.

12. The display panel according to claim 11, wherein
the second light transmitting area is located on a side of the first light transmitting area facing away from the display area; wherein
S1>S2.

13. The display panel according to claim 12, wherein
the display panel further includes a fourth light transmitting area located in the non-display area, the fourth light transmitting area having an area of S4 and being located on a side of the first light transmitting area facing the display area; wherein
S4>S1>S2.

14. The display panel according to claim 13, wherein
$$S 4 - S 1 = S 1 - S 2 , or S 4 / S 1 = S 1 / S 2.$$

15. The display panel according to claim 11, wherein
the first light transmitting area includes a first sub-area and a second sub-area spaced apart along a first predetermined direction, and a distance from the first sub-area to the display area is equal to a distance from the second sub-area to the display area;
and/or, the second light transmitting area includes a third sub-area and a fourth sub-area spaced apart along the first predetermined direction, and a distance from the third sub-area to the display area is equal to a distance from the fourth sub-area to the display area.

16. The display panel according to claim 15, wherein
along a second predetermined direction, the first sub-area and/or the second sub-area are at least partially non-overlapping with the second light transmitting area, the second predetermined direction intersecting the first predetermined direction.

17. The display panel according to claim 11, wherein
the display panel includes a second film layer, the second film layer including a third opening located in the first light transmitting area and a fourth opening located in the second light transmitting area.

18. The display panel according to claim 17, wherein
the second film layer is a metal film layer, the second film layer includes a first signal line, and the first signal line includes the third opening and the fourth opening.

19. The display panel according to claim 1, wherein
the display panel further includes a non-display area at least partially surrounding the display area, the first light transmitting area is located in the display area, and the second light transmitting area is located in the non-display area; wherein
S1>S2.

20. A display device comprising a display panel, wherein the display panel includes:
a display area including a pixel area, the pixel area including light emitting elements; and
a first light transmitting area and a second light transmitting area, the first light transmitting area having an area of S1 and the second light transmitting area having an area of S2; wherein
$$\vert S 1 - S 2 \vert > 0.$$
